(19) United States
(12) Patent Application Publication
(10) Pub. No.: US 2012/0057092 A1
(43) Pub. Date: Mar. 8, 2012

(54) ACTIVE DEVICE ARRAY SUBSTRATE AND LIQUID CRYSTAL PANEL

(75) Inventors: Tsu-Te Zen, Kaohsiung County (TW); Han-Tung Hsu, Taoyuan County (TW)

(73) Assignee: CHUNGHWA PICTURE TUBES, LTD., Taoyuan (TW)

(21) Appl. No.: 12/954,683

(22) Filed: Nov. 26, 2010

(30) Foreign Application Priority Data
Sep. 8, 2010 (TW) 99217413

(51) Int. Cl. G02F 1/136; H01L 27/15

(52) U.S. Cl. 349/43; 257/88; 257/E27.12

(57) ABSTRACT

An active device array substrate including a substrate, a pixel array and a plurality of switching elements used for detection is provided. The substrate has a display area and a peripheral circuit area adjacent with each other. The pixel array is disposed in the display area. The switching elements are disposed in the peripheral circuit area. Each switching element includes a semiconductor layer, and a plurality of first and second electrode branches. The first and second electrode branches are disposed on the semiconductor layer. The first and second electrode branches form a plurality of first conductive channels in a first direction and a plurality of second conductive channels in a second direction via the semiconductor layer. A portion of the lengths of the first conductive channels are the same. A portion of the lengths of the second conductive channels are the same.

### CROSS-REFERENCE TO RELATED APPLICATION

This application claims the priority benefit of Taiwan application serial no. 99217413, filed on Sep. 8, 2010. The entirety of the above-mentioned patent application is hereby incorporated by reference herein and made a part of this specification.

### BACKGROUND OF THE INVENTION

1. Field of the Invention

The invention relates to an array substrate and a panel, and more particularly, to an active device array substrate and a liquid crystal panel with newly designed switching elements used for detection.

2. Description of Related Art

The thin film transistor liquid crystal display (TFT-LCD) has become the mainstream among various flat panel displays for its superior characteristics such as high resolution, good space usage, low power consumption and free of radiation.

The TFT-LCD is made up of a thin film transistor (TFT) array substrate, a color filter substrate, and a liquid crystal layer. After a manufacturing process of the TFT array substrate is completed, an electrical inspection is often performed on a pixel array of the TFT array substrate by using the switching elements used for detection. This is to determine whether the pixel array is operated normally, and proceed with relevant repair action.

FIG. 1 is a detailed structure schematic view of a conventional switching element used for detection. Please referring to FIG. 1, the switching element used for detection 100 is disposed on the peripheral circuit area of the TFT array substrate 50. The switching element used for detection 100 comprises a semiconductor layer 110, an electrode 120, and an electrode 130. The electrode 120 and the electrode 130 are disposed on the semiconductor layer 110, and the electrode 120 and the electrode 130 are comb shape structures that complement each other. When providing voltage to the electrode 120 and the electrode 130, a plurality of conductive channels 140 is fanned in the semiconductor layer 110, causing conduction between the electrode 120 and the electrode 130.

Referring to FIG. 1, reference A is a length of the conductive channel 140 along the second direction D2 (horizontal direction) of the electrode 120 and the electrode 130. Reference B is a length of the conductive channel 140 along the first direction D1 (vertical direction) of the electrode 120 and the electrode 130. The overall length of the conductive channel 140 represents the conductivity of the switching element used for detection 100. It can be seen through calculations that the overall length of the conductive channel 140 consists of 22 of the length A and 21 of the length B. Suppose length A is 79 μm, and length B is 5 μm, then the overall length of the conductive channel 140 is 1,843 μm.

However, as shown in FIG. 1, in the switching element used for detection 100, most of the electrode 120 and the electrode 130 extend along the second direction D2 (horizontal direction), which has a longer length and a larger quantity. Thus, during the etching process to fabricate the electrode 120 and the electrode 130, there is difficulty completing the etching process for the electrode 120 and the electrode 130 along the direction D2 (horizontal direction), causing the electrode 120 and the electrode 130 to still be connected to each other. As such, the switching element used for detection 100 is unable to be fully effective, causing a reduction in the fabrication yield of the TFT array substrate 50.

### SUMMARY OF THE INVENTION

Accordingly, the invention provides an active device array substrate, capable of reducing the electrode length and reducing the probability of an incomplete etching process.

The invention also directs to a liquid crystal panel comprising the active device array substrate.

Based on the above, the invention provides an active device array substrate including a substrate, a pixel array, and a plurality of switching elements used for detection. The substrate includes a display area and a peripheral circuit area adjacent with each other. The pixel array is disposed in the display area. The switching elements used for detection are disposed in the peripheral circuit area. Each switching element includes a semiconductor layer, and a plurality of first and second electrode branches. The plurality of first electrode branches are connected to each other and disposed on the semiconductor layer, and respectively extend along a first direction and a second direction. The plurality of second electrode branches are connected to each other and disposed on the semiconductor layer, and respectively extend along the first direction and the second direction. In the first direction, the first electrode branches and the second electrode branches fon u a plurality of first conductive channels via the semiconductor layer. A portion of the lengths of the first conductive channels are the same. In the second direction, the first electrode branches and the second electrode branches form a plurality of second conductive channels via the semiconductor layer. A portion of the lengths of the second conductive channels are the same. Wherein, a pattern formed by the first electrode branches complements a pattern formed by the second electrode branches.

The invention also provides a liquid crystal panel including an active device array substrate, a color filter substrate, and a liquid crystal layer. The active device array substrate includes a substrate, a pixel array, and a plurality of switching elements used for detection. The substrate includes a display area and a peripheral circuit area adjacent with each other. The pixel array is disposed in the display area. The switching elements used for detection are disposed in the peripheral circuit area. Each switching element includes a semiconductor layer, and a plurality of first and second electrode branches. The plurality of first electrode branches are connected to each other and disposed on the semiconductor layer, and respectively extend along a first direction and a second direction. The plurality of second electrode branches are connected to each other and disposed on the semiconductor layer, and respectively extend along the first direction and the second direction. In the first direction, the first electrode branches and the second electrode branches form a plurality of first conductive channels via the semiconductor layer, a portion of the lengths of the first conductive channels are the same. In the second direction, the first electrode branches and the second electrode branches fan 1 a plurality of second conductive channels via the semiconductor layer. A portion of the lengths of the second conductive channels are the same. The color filter substrate is disposed opposite to the active device array substrate. The liquid crystal layer is disposed between the active device array substrate and the color filter substrate. Wherein, a pattern formed by the first electrode branches complements a pattern formed by the second electrode branches.

In an embodiment of the invention, an angle is between the first direction and the second direction.

In an embodiment of the invention, the first direction is perpendicular to the second direction.

In an embodiment of the invention, the shape of each of the first electrode branches and the shape of each of the second electrode branches comprise a strip shape or a wave shape.

In an embodiment of the invention, a portion of the lengths of the first electrode branches are the same, and a portion of the lengths of the second electrode branches are the same.

In an embodiment of the invention, in a first area of each of the plurality of switching elements used for detection, the first electrode branches surround the second electrode branches. In an embodiment of the invention, in a second area and a third area of each of the plurality of switching elements used for detection, the second electrode branches surround the first electrode branches. The first area is disposed between the second area and the third area.

In an embodiment of the invention, a pattern of the second area and a pattern of the third area are mirror patterns with respect to each other.

In an embodiment of the invention, a pattern of the second area and a pattern of the third area are respectively a symmetrical pattern.

The active device array substrate and liquid crystal panel of the invention adopts newly designed switching elements used for detection. Each switching element used for detection comprises a plurality of first electrode branches and a plurality of second electrode branches. The first electrode branches are connected to each other and respectively extend along the first direction and the second direction. The second electrode branches are connected to each other and respectively extend along the first direction and the second direction. Thereby, in different directions, a portion of the lengths of the conductive channels are the same and can be respectively formed. Thus, most of the first and the second electrode branches can be determined with suitable lengths, and can proceed with complete etching As such, the fabrication yield of the switching elements used for detection is enhanced, and the switching elements used for detection still have good conductivity.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 is a detailed structure schematic view of a conventional switching element used for detection.

FIG. 2 is a schematic cross-sectional view of a liquid crystal panel according to an embodiment of the invention.

FIG. 3 is a schematic view of the active device array substrate in FIG. 2.

FIG. 4 is a detailed structure schematic view of the switching element used for detection in FIG. 3.

FIG. 5 is a detailed structure schematic view of a switching element used for detection in another embodiment of the invention.

FIG. 6 is a detailed structure schematic view of a switching element used for detection in yet another embodiment of the invention.

### DESCRIPTION OF EMBODIMENTS

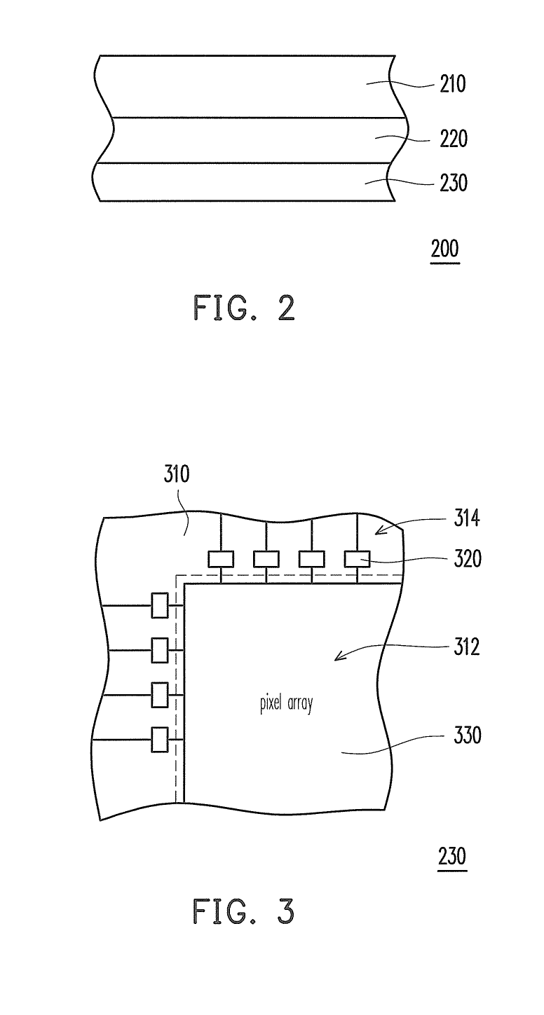

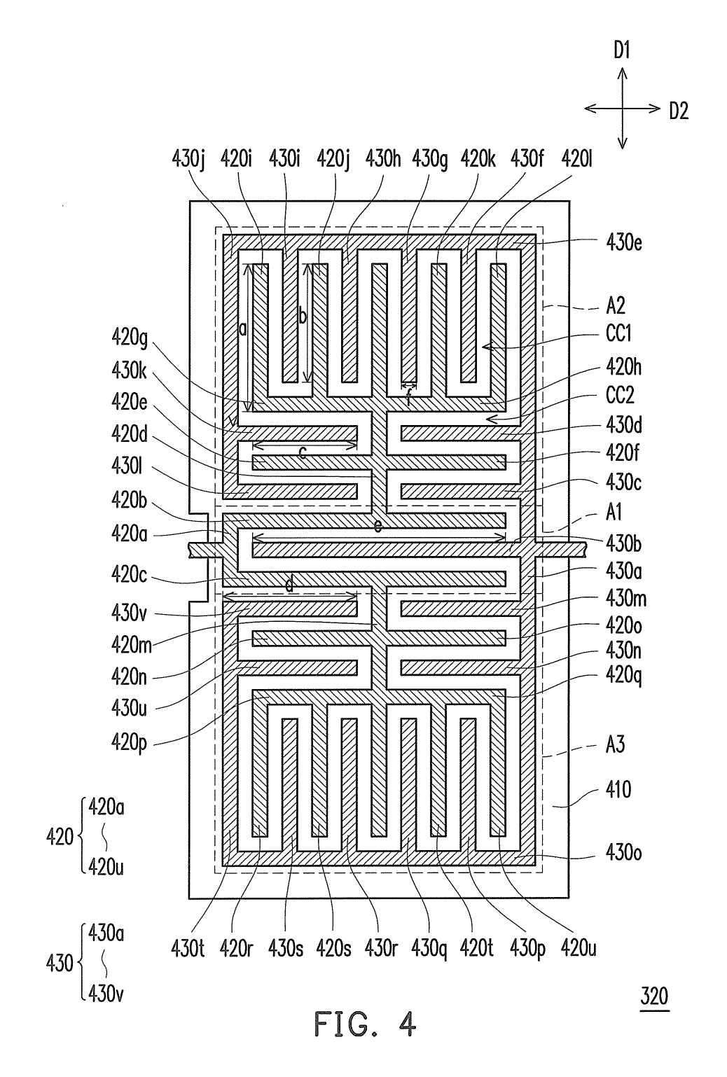

FIG. 2 is a schematic cross-sectional view of a liquid crystal panel according to an embodiment of the invention. Referring to FIG. 2, an LCD panel 200 includes a color filter substrate 210, a liquid crystal layer 220, and an active device array substrate 230. The color filter substrate 210 is disposed opposite to the active device array substrate 230. The liquid crystal layer 220 is disposed between the active device array substrate 230 and the color filter substrate 210. The liquid crystal panel 200 has newly designed switching elements used for detection 320 which are disposed in the peripheral circuit area 314 of the active device array substrate 230. Please further refer to the illustrations in FIG. 3 and FIG. 4.

FIG. 3 is a schematic view of the active device array substrate in FIG. 2. FIG. 4 is a detailed structure schematic view of the switching element used for detection in FIG. 3. Please referring to FIG. 3 and FIG. 4, the active device array substrate 230 may includes: a substrate 310, switching elements used for detection 320, and a pixel array 330. The substrate 310 includes a display area 312 and a peripheral circuit area 314 adjacent with each other. The pixel array 330 is disposed in the display area 312. The switching elements used for detection 320 are disposed in the peripheral circuit area 314. Enabling the switching elements used for detection 320 is used to lighten all the pixels (not shown) of the pixel array 330, and proceed with related tests.

Please referring to FIG. 4, the switching element used for detection 320 comprises a semiconductor layer 410, a first electrode 420, and a second electrode 430. The first electrode 420 includes a plurality of first electrode branches 420a˜420u. The second electrode 430 includes a plurality of second electrode branches 430a˜430v. Seen from FIG. 4, the switching element used for detection 320 comprises a distinct electrode design.

In further detail, the first electrode branches 420a˜420u are connected to each other and disposed on the semiconductor layer 410, and respectively extends along a first direction D1 and a second direction D2. The second electrode branches 430a˜430v are connected to each other and disposed on the semiconductor layer 410, and respectively extends along the first direction D1 and the second direction D2. The first direction D1 can be perpendicular to the second direction D2.

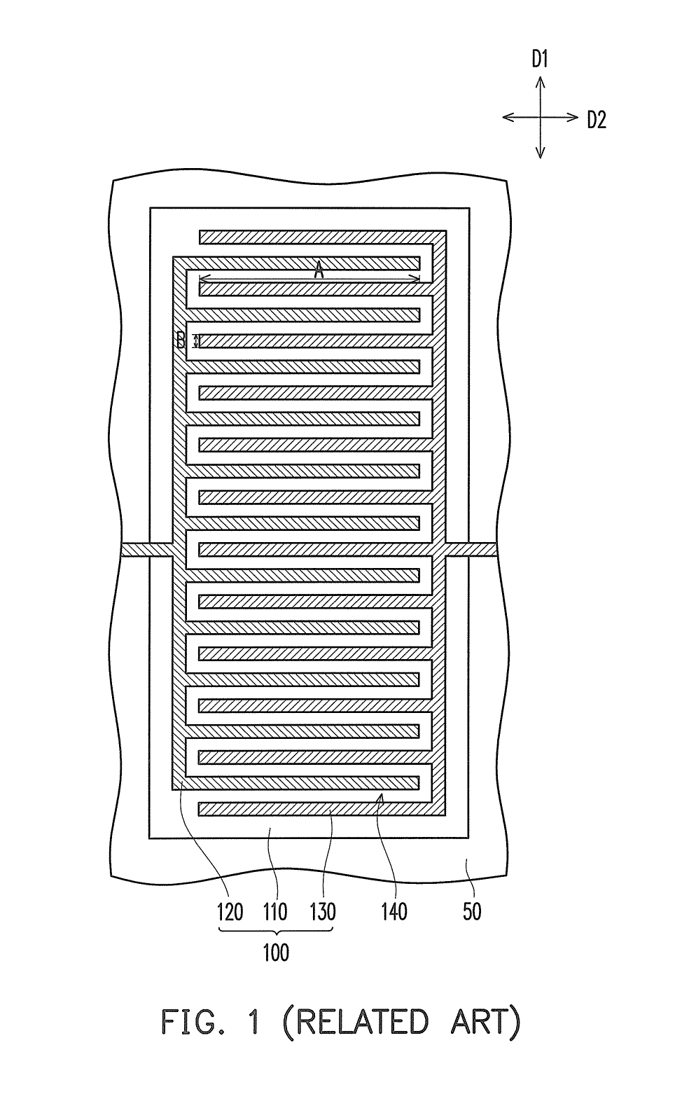

It should be noted that a portion of the lengths of the first electrode branches 420a˜420u are the same, and a portion of the lengths of the second electrode branches 430a˜430v are the same. In other words, a plurality of first electrode branches 420a˜420u of different lengths and a plurality of second electrode branches 430a˜430v of different lengths are uniformly disposed on the first direction D1 and the second direction D2. Using this design, the problem of a length of the electrode in a single direction (such as the first direction D1 shown in FIG. 1) being too long causing incomplete etching can be avoided.

As shown in FIG. 4, the shape of the first electrode branches 420a˜420u and the shape of the second electrode branches 430a˜430v can be stripe shaped. In addition, the pattern formed by the first electrode branches 420a˜420u can complement the pattern formed by the second electrode branches 430a˜430v. The shape of the first electrode branches 420a˜420u and the shape of the second electrode branches 430a˜430v complement each other, forming a plurality of conductive channels between the first electrode branches 420a˜420u and the second electrode branches 430a˜430v.

Referring to FIG. 4, the disposing manner of the first electrode 420 and the second electrode 430 is further described hereinafter. In order to simplify the description, the pattern formed by the first electrode branches 420a˜420u and the second electrode branches 430a˜430v is marked off by a first area A1, a second area A2, and a third area A3. The first area A1 is located between the second area A2 and the third area A3.

The structure of the first electrode 420 is described below:

In the first area A1, the first electrode branch 420a extends along the first direction D1. The first electrode branches 420b and 420c extend along the second direction D2. The first electrode branches 420b and 420c respectively connect to the two ends of the first electrode branch 420a.

In the second area A2, the first electrode branch 420d extends along the first direction D1 and connects with the first electrode branch 420b. The connecting point of the first electrode branches 420b and 420d is close to the midpoint of the first electrode branch 420b. The first electrode branches 420e, 420f, 420g, and 420h extend along the second direction D2, and respectively connect to the first electrode branch 420d. The first electrode branch 420e is opposite to the first electrode branch 420f. The first electrode branch 420g is opposite to the first electrode branch 420h. In addition, the first electrode branches 420i, 420j, 420k, and 4201 extend along the first direction D1. The first electrode branches 420i and 420j respectively connect to the first electrode branch 420g. The first electrode branches 420k and 420l respectively connect to the first electrode branch 420h.

In the third area A3, the first electrode branch 420m extends along the first direction D1 and connects with the first electrode branch 420c. The connecting point of the first electrode branches 420c and 420m is close to the midpoint of the first electrode branch 420c. The first electrode branches 420n, 420o, 420p, and 420q extend along the second direction D2, and respectively connect to the first electrode branch 420m. The first electrode branch 420n is opposite to the first electrode branch 420o. The first electrode branch 420p is opposite to the first electrode branch 420q. The first electrode branches 420r˜420u extend along the first direction D1. The first electrode branches 420r and 420s respectively connect to the first electrode branch 420p. The first electrode branches 420t and 420u respectively connect to the first electrode branch 420q.

The structure of the second electrode 430 is described below:

The second electrode branch 430a extends along the first direction D1, and extends across the first area A1, the second area A2, and the third area A3. In the first area A1, the second electrode branch 430b extends along the second direction D2 and connects with the second electrode branch 430a. The connecting point of the second electrode branch 430a and the second electrode branch 430b is close to the midpoint of the second electrode branch 430a.

In the second area A2, the second electrode branches 430c, 430d, and 430e extend along the second direction D2, and respectively connect to the second electrode branch 430a. The second electrode branch 430e is connected to an end of the second electrode branch 430a. The second electrode branch 430c extends between the first electrode branches 420b and 420f. The second electrode branch 430d extends between the first electrode branches 420f and 420h.

In addition, the second electrode branches 430f, 430g, 430h, 430i, and 430j extend along the first direction D1, and respectively connect to the second electrode branch 430e. The second electrode branch 430j is connected to an end of the second electrode branch 430e. The second electrode branch 430f extends between the first electrode branches 420l and 420k. The second electrode branch 430g extends between the first electrode branches 420d and 420k. The second electrode 430h extends between the first electrode branches 420d and 420j. The second electrode 430i extends between the first electrode branches 420i and 420j. Furthermore, the second electrode branches 430k and 430l extend along the second direction D2, and respectively connect to the second electrode branch 430j. The second electrode branch 430k extends between the first electrode branches 420e and 420g. The second electrode branch 430l is connected to an end of the second electrode branch 430j and extends between the first electrode branches 420b and 420e.

In the third area A3, the second electrode branches 430m, 430n, and 430o extend along the second direction D2, and respectively connect to the second electrode branch 430a. The second electrode branch 430o is connected to an end of the second electrode branch 430a. The second electrode branch 430m extends between the first electrode branches 420c and 420o. The second electrode branch 430n extends between the first electrode branches 420o and 420q.

The second electrode branches 430p, 430q, 430r, 430s, and 430t extend along the first direction D1, and respectively connect to the second electrode branch 430o. The second electrode branch 430t is connected to an end of the second electrode branch 430o. The second electrode branch 430p extends between the first electrode branches 420t and 420u. The second electrode branch 430q extends between the first electrode branches 420m and 420t. The second electrode branch 430r extends between the first electrode branches 420m and 420s. The second electrode branch 430s extends between the first electrode branches 420r and 420s. Furthermore, the second electrode branches 430u and 430v extend along the second direction D2, and respectively connect to the second electrode branch 430t. The second electrode branch 430u extends between the first electrode branches 420n and 420p. The second electrode branch 430v is connected to an end of the second electrode branch 430t and extends between the first electrode branches 420c and 420n.

As shown in FIG. 4, in the first area A1, the first electrode branches 420a, 420b, and 420c surround the second electrode branches 430a and 430b. In the second area A2, the second electrode branches 430a, 430c˜430l surround the first electrode branches 420d˜420l. In the third area A3, the second electrode branches 430a, 430m˜430v surround the first electrode branches 420m˜420u. Also, the pattern in the second area A2 and the pattern in the third area A3 are mirror patterns with respect to each other. The pattern of the second area A2 and the pattern of the third area A3 are respectively a symmetrical pattern.

From the above, in the first direction D1, the first electrode branches 420a˜420u and the second electrode branches 430a˜430v form a plurality of first conductive channels CC1 via the semiconductor layer 410. A portion of the lengths of the first conductive channels CC1 are the same. In the second direction D2, the first electrode branches 420a˜420u and the second electrode branches 430a˜430v also foam a plurality of second conductive channels CC2 via the semiconductor layer 410. A portion of the lengths of the second conductive channels CC2 are also the same.

Through the pattern design of the first electrode branches 420a˜420u and the second electrode branches 430a˜430v, most of the lengths of the first conductive channels CC1 and the second conductive channels CC2 are designed with a length easier to be completely etched (for example, the length can be less than or equal to 50 μm). This reduces the probability of incomplete etching, and raises the fabrication yield of the switching elements used for detection 320.

The switching elements used for detection 320 still have good conductivity. Similarly, the overall length of the conductive channels represents the conductivity of the switching element used for detection 320. It can be seen through calculations that the overall length of the conductive channels (CC1, CC2) consist of 4 lengths of a, 16 lengths of b, 12 lengths of c, 4 lengths of d, 2 lengths of e, and 33 lengths of f. The lengths a, b, and parts of the length e are the parallel lengths of the first electrode branches 420a˜420u and the second electrode branches 430a˜430v along the first direction D1. The lengths c, d, f, and the remaining lengths of e are the parallel lengths of the first electrode branches 420a˜420u and the second electrode branches 430a˜430v along the second direction D2.

Assuming the length a is equal to 53 μm, the length b is equal to 43 μm, the length c is equal to 35 μm, the length d is equal to 45 μm, the length e is equal to 85 μm, and the length f is equal to 5 μm, then the overall length of the conductive channels (CC1, CC2) is 1,835 μm. Compared to the overall length (1,843 μm) of the conductive channels 140 of the conventional switching element used to for detection 100 in FIG. 1, the conductivity of the switching elements used for detection 320 is substantially close to the signal conductivity of the switching element used for detection 100. It should be noted that the length of the first and second electrode 420, 430 of the switching element used for detection 320 is comparably shorter and easier to be completely etched. Thus, the fabrication yield of the switching element used for detection 320 is raised.

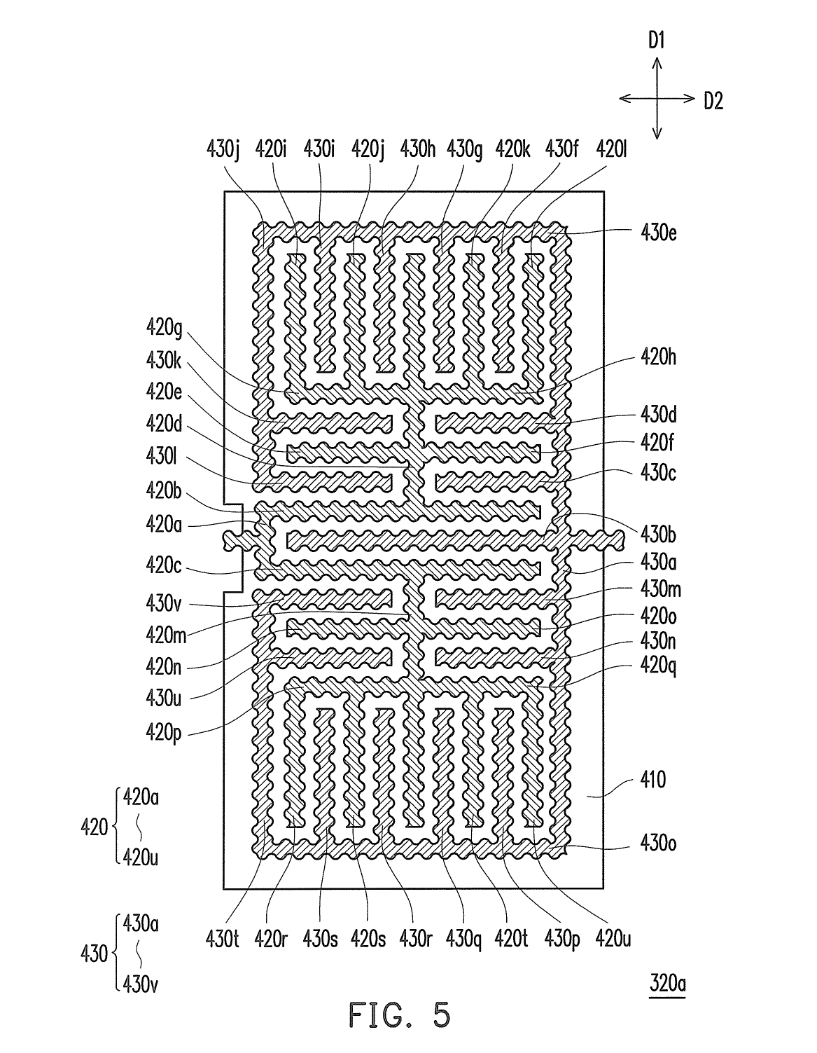

FIG. 5 is a detailed structure schematic view of a switching element used for detection in another embodiment of the invention. Referring to FIG. 5, the structure of a switching element used for detection 320a is similar to the switching element used for detection 320 in FIG. 4, thus the same components are denoted with the same notations and the descriptions thereof are omitted hereinafter. In should be noted that as shown in FIG. 5, the shape of the first electrode branches 420a˜420u and the shape of the second electrode branches 430a˜430v are wave shaped. Of course, the shape of the first electrode branches 420a˜420u and the shape of the second electrode branches 430a˜430v can be other suitable, arbitrary shapes.

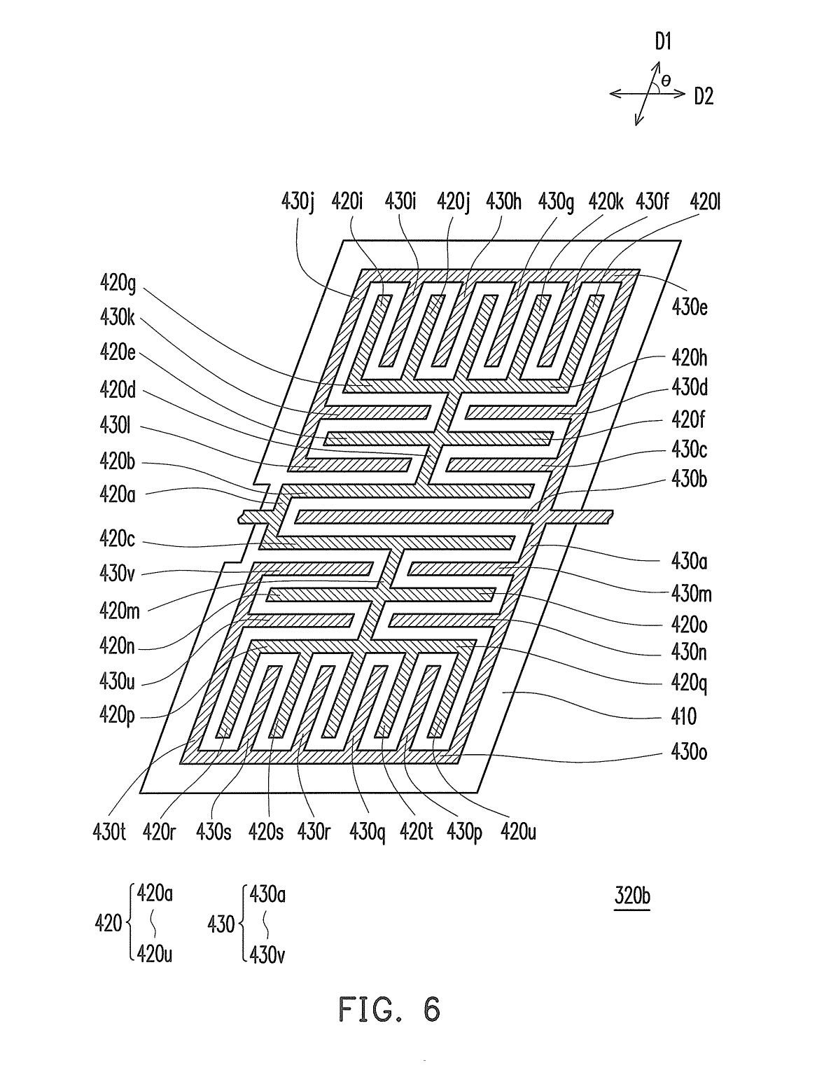

FIG. 6 is a detailed structure schematic view of a switching element used for detection in yet another embodiment of the invention. Referring to FIG. 6, the structure of a switching element used for detection 320b is similar to the switching element used for detection 320 in FIG. 4, thus the same components are denoted with the same notations and the descriptions thereof are omitted hereinafter. It should be noted that in the switching element used for detection 320b in FIG. 6, there is an angle θ between the first direction D1 and the second direction D2, and the angle θ is less than 90 degrees. Of course, the angle can be an arbitrary, suitable angle.

In summary, the active device array substrate and the liquid crystal panel of the embodiment of the invention has at least the following advantages:

Each switching element used for detection comprises a plurality of first electrode branches and a plurality of second electrode branches. The first electrode branches are connected to each other and respectively extend along the first direction and the second direction. The second electrode branches are connected to each other and respectively extend along the first direction and the second direction. Thereby, the first electrode branches and the second electrode branches of suitable lengths are disposed in the first direction and the second direction disposes, and so most of the conductive channels are designed with a length easier to be completely etched. As such, the fabrication yield of the switching elements used for detection is raised, and the switching elements used for detection continue to have good conductivity.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. An active device array substrate, comprising:
a substrate, including a display area and a peripheral circuit area adjacent with each other;
a pixel array disposed in the display area;
a plurality of switching elements used for detection, disposed in the peripheral circuit area, each of the plurality of switching elements used for detection comprises:
a semiconductor layer;
a plurality of first electrode branches, connected to each other and disposed on the semiconductor layer, and respectively extends along a first direction and a second direction;
a plurality of second electrode branches, connected to each other and disposed on the semiconductor layer, and respectively extends along the first direction and the second direction;
wherein, in the first direction, the first electrode branches and the second electrode branches form a plurality of first conductive channels via the semiconductor layer, a portion of the lengths of the first conductive channels are the same; and
in the second direction, the first electrode branches and the second electrode branches form a plurality of second conductive channels via the semiconductor layer, a portion of the lengths of the second conductive channels are the same,
wherein, a pattern formed by the first electrode branches complements a pattern formed by the second electrode branches.

2. The active device array substrate of claim 1, wherein an angle is between the first direction and the second direction.

3. The active device array substrate of claim 2, wherein the first direction is perpendicular to the second direction.

4. The active device array substrate of claim 1, wherein the shape of each of the plurality of first electrode branches and the shape of each of the plurality of second electrode branches comprise a strip shape or a wave shape.

5. The active device array substrate of claim 1, wherein a portion of the lengths of the first electrode branches are the same, and a portion of the lengths of the second electrode branches are the same.

6. The active device array substrate of claim 1, wherein in a first area of each of the plurality of switching elements used for detection, the first electrode branches surround the second electrode branches,
in a second area and a third area of each of the plurality of switching elements used for detection, the second electrode branches surround the first electrode branches,
the first area is disposed between the second area and the third area.

7. The active device array substrate of claim 6, wherein a pattern of the second area and a pattern of the third area are minor patterns with respect to each other.

8. The active device array substrate of claim 6, wherein a pattern of the second area and a pattern of the third area are respectively a symmetrical pattern.

9. A liquid crystal panel, comprising:
an active device array substrate, comprising:
a substrate, including a display area and a peripheral circuit area adjacent with each other;
a pixel array disposed in the display area;
a plurality of switching elements used for detection, disposed in the peripheral circuit area, each of the plurality of switching elements used for detection comprises:
a semiconductor layer;
a plurality of first electrode branches, connected to each other and disposed on the semiconductor layer, and respectively extends along a first direction and a second direction;
a plurality of second electrode branches, connected to each other and disposed on the semiconductor layer, and respectively extends along the first direction and the second direction;
wherein, in the first direction, the first electrode branches and the second electrode branches form a plurality of first conductive channels via the semiconductor layer, a portion of the lengths of the first conductive channels are the same; and
in the second direction, the first electrode branches and the second electrode branches form a plurality of second conductive channels via the semiconductor layer, a portion of the lengths of the second conductive channels are the same;
a color filter substrate, disposed opposite to the active device array substrate; and
a liquid crystal layer, disposed between the active device array substrate and the color filter substrate,
wherein, a pattern formed by the first electrode branches complements a pattern formed by the second electrode branches.

10. The liquid crystal panel of claim 9, wherein an angle is between the first direction and the second direction.

11. The liquid crystal panel of claim 10, wherein the first direction is perpendicular to the second direction.

12. The liquid crystal panel of claim 9, wherein the shape of each of the plurality of first electrode branches and the shape of each of the plurality of second electrode branches comprise a strip shape or a wave shape.

13. The liquid crystal panel of claim 9, wherein a portion of the lengths of the first electrode branches are the same, and a portion of the lengths of the second electrode branches are the same.

14. The liquid crystal panel of claim 9, wherein in a first area of each of the plurality of switching elements used for detection, the first electrode branches surround the second electrode branches,
in a second area and a third area of each of the plurality of switching elements used for detection, the second electrode branches surround the first electrode branches,
the first area is disposed between the second area and the third area.

15. The liquid crystal panel of claim 14, wherein a pattern of the second area and a pattern of the third area are mirror patterns with respect to each other.

16. The liquid crystal panel of claim 14, wherein a pattern of the second area and a pattern of the third area are respectively a symmetrical pattern.
